(19) United States
(12) Patent Application Publication
(10) Pub. No.: US 2025/0336664 A1
(43) Pub. Date: Oct. 30, 2025

(54) GAS ATOMIZED PREWETTING CHAMBER AND CLEANING SYSTEM AND METHOD

(71) Applicant: APPLIED Materials, Inc., Santa Clara, CA (US)

(72) Inventors: Paul R. McHugh, Kalispell, MT (US); Benjamin Bradley, Whitefish, MT (US); Randy A. Harris, Kalispell, MT (US)

(73) Assignee: APPLIED Materials, Inc., Santa Clara, CA (US)

(21) Appl. No.: 18/649,977

(22) Filed: Apr. 29, 2024

(51) Int. Cl. H01L 21/02; H01L 21/67

(52) U.S. Cl. CPC H01L 21/02057; H01L 21/67051

(57) ABSTRACT

A semiconductor substrate wetting and cleaning system includes a processing chamber (12) and a rotatable head disposed in the processing chamber. A coupler or chuck (24) couples a semiconductor substrate or wafer (18) to the rotatable head. At least one gas atomized spray nozzle (20) is directed at the semiconductor substrate (18) when coupled to the coupler. A source (21) of wetting/cleaning fluid is in flow communication with the spray nozzle (20), and a source (23) of atomizing gas also is in flow communication with the spray nozzle (20) to atomize the wetting/cleaning fluid.

### BACKGROUND

Integrated circuits are constructed by processes which produce intricately patterned material layers on wafer or other substrate surfaces. Commonly used wafer materials include, for example, silicon carbide, aluminum nitride, and aluminum oxide. Producing patterned conductive material on the wafer requires controlled methods for applying and removing material. For removal, chemical or physical etching may be performed for a variety of purposes, including transferring a pattern in photoresist into underlying layers, thinning layers, or thinning lateral dimensions of features already present on the surface. Once a material has been etched or otherwise processed, the substrate or material layers are cleaned and/or prepared for further operations.

A typical wafer plating process involves depositing a metal seed layer onto the surface of the wafer via vapor deposition. A photoresist may be deposited and patterned to expose the seed layer. The wafer is then moved into the vessel of an electroplating processor where electric current is conducted through an electrolyte to the wafer, to apply a blanket layer or patterned layer of a metal or other conductive material onto the seed layer. Examples of conductive materials include permalloy, gold, silver, copper, cobalt, tin, and alloys of these metals. Subsequent processing steps form components, contacts, and/or conductive lines on the wafer to allow electricity to conduct through the device from layer to layer. As device features continue to shrink in size, so too does the amount of metal providing conductive pathways through the substrate. As the amount of metal is reduced, the quality of the plated materials and coating thereof may become more critical to ensure adequate electrical conductivity through the device.

Vacuum pre-wetting is a pre-plating step used in increasing plating quality, especially with features having high aspect ratios. In pre-wetting, gas is removed from the features and the features are filled with a pre-plating solution, for example, de-ionized (DI) water.

By fully wetting the features before the wafer enters the plating solution, metal ions in the plating solution can better diffuse into the water and fully fill the feature when plating begins. A common problem of un-wetted features is that the metal ions in the plating solution cannot reach the bottom of the feature often due to a bubble of gas trapped in the feature. The trapped gas bubble tends to cause the plated metal to pinch off, leaving a void at the bottom of the feature, which results in a defect, such as an unconnected circuit line.

In addition, residual process materials from preceding process steps may remain in vias due to inadequate preclean. Such residual materials and/or particles may also serve as blocking sites to plating chemistries and operations. When features do not receive adequate plating, the interconnect functions may not operate effectively, which may lead to device issues or failure.

Pre-wetting can be achieved by immersing the substrate into a bath of liquid, e.g., DI water, or by spraying liquid onto the substrate. However, as substrates are patterned with increasingly smaller trenches and vias, existing pre-wetting techniques have become less reliable. Surface tension and other effects can prevent the liquid from contacting all surfaces of the substrate, especially recessed feature surfaces. Larger features having high aspect ratios may also not be consistently fully wetted by immersion or spraying. This can result in defects during follow-on manufacturing steps, such as plating steps, where voids and mis-filled features may occur at localized microscopic areas of the substrate.

Various approaches for improved pre-wetting and cleaning have been used, including the use of solvents, surfactants, or other chemicals. Other approaches include use of a vacuum and DI water. These approaches have met with varying degrees of success and disadvantages remain. For example, the techniques using these chemicals do not necessarily eliminate all localized microscopic dry areas. These techniques also generally require additional manufacturing steps and equipment, in addition to the complications and costs of obtaining and using the chemicals. Use of such chemicals may also affect later processing steps and create chemical compatibility problems.

The present disclosure seeks to improve upon existing systems and methods to produce high quality devices and structures.

### SUMMARY

This summary is provided to introduce a selection of concepts in a simplified form that are further described below in the Detailed Description. This summary is not intended to identify key features of the claimed subject matter, nor is it intended to be used as an aid in determining the scope of the claimed subject matter.

In accordance with one embodiment of the present disclosure, a method of processing a semiconductor substrate defining a plurality of features is provided. The method includes spraying the substrate with a gas atomized wetting and cleaning agent, rotating the semiconductor substrate during the spraying, and wetting and cleaning the plurality of features defined in the substrate with the gas atomized wetting and cleaning agent.

In any of the embodiments described herein, wherein the atomizing gas has a higher solubility in the wetting and cleaning agent than oxygen.

In any of the embodiments described herein, wherein the atomizing gas is selected from the group consisting of carbon dioxide and nitrogen

In any of the embodiments described herein, wherein the atomizing gas is selected from the group consisting of carbon dioxide, nitrogen, air.

In any of the embodiments described herein, further comprising moving the spray of the gas atomized wetting and cleaning agent about the surface of the semiconductor substrate.

In any of the embodiments described herein, further comprising applying a purge gas to the semiconductor substrate, the purge gas selected from the group consisting of carbon dioxide, common nitrogen, air.

In any of the embodiments described herein, wherein the semiconductor wafer is located in an atmosphere selected from the group consisting of an open atmosphere environment and a closed atmosphere environment.

In any of the embodiments described herein, further comprising applying a vacuum to the semiconductor substrate.

In any of the embodiments described herein, wherein the gas atomized wetting and cleaning fluid comprising 1-1500 milliliter per minute of wetting and cleaning agent, and 15-200 liters per minute of atomizing gas.

In any of the embodiments described herein, wherein the gas atomized wetting and cleaning fluid comprising 1-100 milliliters per minute of wetting and cleaning agent, and 15-100 liters per minute of atomizing gas.

In any of the embodiments described herein, wherein the processing duration is from selected from the group consisting of 30 to 500 seconds and 30 to 120 seconds.

In any of the embodiments described herein, wherein the rotational speed of the substrate is selected from the group consisting of from 1 to 1000 revolutions per minute and from 1 to 500 revolutions per minute.

In accordance with another embodiment of the present disclosure, a method of treating a semiconductor substrate defining a plurality of features with a wetting and cleaning agent is provided. The method includes forming in an atmosphere within which the semiconductor substrate is disposed a gas having a higher solubility with the wetting agent then oxygen, spraying the substrate with a gas atomized wetting and cleaning agent, and wetting and cleaning the plurality of features defined in the substrate with the gas atomized wetting and cleaning agent.

In any of the embodiments described herein, wherein the atomizing gas is selected from the group consisting of carbon dioxide, nitrogen and air.

In any of the embodiments described herein, wherein the wetting and cleaning agent is selected from the group consisting of deionized water, aqueous solution.

In any of the embodiments described herein, wherein the gas atomized wetting and cleaning agent comprises 1-1500 milliliter per minute of wetting agent, and 15-200 liters per minute of atomizing gas.

In any of the embodiments described herein, wherein the gas atomized wetting and cleaning agent comprising:
1-100 milliliters per minute of wetting agent; and
15-100 liters per minute of atomizing gas.

In any of the embodiments described herein, wherein the treatment duration is selected from the group of from 30 to 500 seconds and from 30 to 120 seconds.

In any of the embodiments described herein, further comprising rotating the substrate at a rotational rate selected from the group consisting of from 1 to 1000 revolutions per minute and from 1 to 500 revolutions per minute.

In any of the embodiments described herein, further comprising applying a vacuum to the semiconductor substrate.

In accordance with another embodiment of the present disclosure, a semiconductor substrate wetting and cleaning system is provided. The semiconductor substrate wetting and cleaning system includes a processing chamber, a rotatable head disposed in the processing chamber, a coupler for coupling a semiconductor substrate to the rotatable head, at least one gas atomized spray nozzle directed at the semiconductor substrate when coupled to the coupler, a source of pre-wetting and cleaning fluid in flow communication with the spray nozzle, and a source of atomizing gas in flow communication with the spray nozzle.

In any of the embodiments described herein, wherein the pre-wetting fluid is selected from the group consisting of deionized water and aqueous solution.

In any of the embodiments described herein, wherein the atomizing gas is selected from the group consisting of carbon dioxide, nitrogen, air.

In any of the embodiments described herein, comprising a plurality of gas atomized spray nozzles configured to move about the semiconductor substrate.

In any of the embodiments described herein, further comprising an actuator to which the at least one atomizing spray nozzle is mounted, the actuator moving the at least one atomizing spray nozzle about the area of the semiconductor substrate.

In any of the embodiments described herein, further comprising a source of atmospheric gas in flow communication with the processing chamber, the atmospheric gas comprised of at least one of carbon dioxide, nitrogen, air.

In any of the embodiments described herein, wherein the chamber is closed relative to the ambient.

In any of the embodiments described herein, further comprising a source of vacuum in flow communication with the processing chamber.

### DESCRIPTION OF THE DRAWINGS

The foregoing aspects and many of the attendant advantages of this invention will become more readily appreciated as the same become better understood by reference to the following detailed description, when taken in conjunction with the accompanying drawings, wherein:

FIG. 1 is a schematic view of an embodiment of a semiconductor wetting and cleaning system of the present disclosure;

FIG. 2 is a schematic view of another embodiment of a semiconductor wetting and cleaning system of the present disclosure; and

FIG. 3 is a schematic view of another embodiment of a semiconductor wetting and cleaning system of the present disclosure.

### DETAILED DESCRIPTION

The description set forth below in connection with the appended drawings, where like numerals reference like elements, is intended as a description of various embodiments of the disclosed subject matter and is not intended to represent the only embodiments.

Each embodiment described in this disclosure is provided merely as an example or illustration and should not be construed as preferred or advantageous over other embodiments. The illustrative examples provided herein are not intended to be exhaustive or to limit the disclosure to the precise forms disclosed. Similarly, any steps described herein may be interchangeable with other steps, or combinations of steps, in order to achieve the same or substantially similar result.

In the following description, numerous specific details are set forth in order to provide a thorough understanding of exemplary embodiments of the present disclosure. It will be apparent to one skilled in the art, however, that many embodiments of the present disclosure may be practiced without some or all of the specific details. In some instances, well-known process steps have not been described in detail in order not to unnecessarily obscure various aspects of the present disclosure. Further, it will be appreciated that embodiments of the present disclosure may employ any combination of features described herein.

The present application may include references to “directions,” such as “forward,” “rearward,” “front,” “back,” “ahead,” “behind,” “upward,” “downward,” “above,” “below,” “horizontal,” “vertical,” ““top,” “bottom,” “right hand,” “left hand,” in,” “out,” “extended,” “advanced,” “retracted,” “proximal,” and “distal.” These references and other similar references in the present application are only to assist in helping describe and understand the present disclosure and are not intended to limit the present invention to these directions.

The present application may include modifiers such as the words “generally,” “approximately,” “about,” or “substantially.” These terms are meant to serve as modifiers to indicate that the “dimension,” “shape,” “temperature,” “time,” or other physical parameter in question need not be exact but may vary as long as the function that is required to be performed can be carried out. For example, in the phrase “generally circular in shape,” the shape need not be exactly circular as long as the required function of the structure in question can be carried out.

In the present application, the terms “wetting” and “prewetting” are used synonymously. Also, in the present application with respect to wetting and prewetting and cleaning, the terms “liquid”, “agent” and “fluid” are used synonymously.

Unless the context indicates otherwise, references to a wetting liquid, fluid, or agent should also be considered to apply a cleaning liquid, fluid or agent. Likewise, unless the context indicates otherwise, references to a cleaning liquid, fluid, or agent should also be considered to apply a wetting or prewetting liquid, fluid or agent

In the following description and in the accompanying drawings, corresponding systems, assemblies, apparatus, and units may be identified by the same part number, but with an alpha suffix. The descriptions of the parts/components of such systems assemblies, apparatus, and units that are the same or similar are not repeated so as to avoid redundancy in the present application.

Efforts to improve both air bubble entrapment and residue removal from features in semiconductor wafers during wetting operations include dipping the wafer into a wetting liquid under vacuum. When the vacuum is removed, bubbles present will shrink, allowing more complete removal. However, such a process fails to fully remove all bubbles, and also fails to remove residues present.

Conventional methods have also utilized spraying wetting chemistries onto substrates. While such efforts have improved the cleaning of residual materials, standard spraying operations typically are insufficient for removal of entrapped bubbles.

Other efforts include displacing air in the chamber with a gas having a higher solubility in water or aqueous solutions than air and utilizing a spray operation to coat the substrate with a wetting agent, which may be DI water or an aqueous solution. In this manner, air bubbles present may be replaced with gas or gas bubbles that may more easily dissolve into the aqueous solution. In addition, the sprayed aqueous solution seeks to clean residues present while removing bubbles.

Nonetheless, it is still difficult for the spray to reach the full depths of the wafer features, to thereby remove entrapped air or residue trapped therein. To address this situation, the present disclosure utilizes an atomizing gas to atomize the wetting agent sprayed onto the wafer.

In a first embodiment of the present disclosure, the processing system 10 includes an open top chamber 12 in the form of a base unit 13 having sidewalls 14 and the base 16 for collecting the gas atomized wetting fluid applied to the top surface of a wafer 18 by a spray nozzle 20. A drain 22 is provided to remove the wetting/cleaning fluid from the chamber 12. The wafer 18 is mounted on a chuck 24 which is rotated by a motor 26.

The spray nozzle 20 is mounted on the distal end of a swing arm 30 that is capable of moving relative to the wafer 18. The direction of this movement can be in numerous directions relative to the top surface of the wafer, including radially with respect to the rotational axis 32 of the wafer as well as in an arc about the proximal end of the swing arm. The swing arm 30 is mounted to a mounting structure 34 which may be capable of raising and lowering the elevation of the swing arm to move the spray nozzle 20 closer to or further away from the wafer 18.

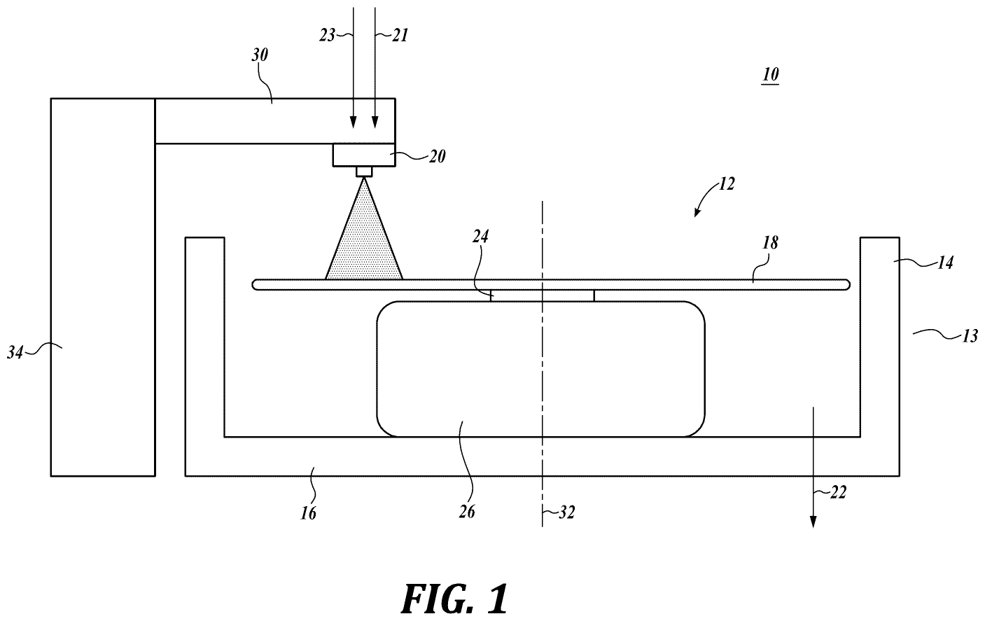

The spray nozzle 20 is capable of receiving and expelling a wetting and/or cleaning liquid such as the deionized water or other aqueous solution from a source such as schematically shown in FIG. 1 as 21. The spray nozzle 20 is also capable of receiving and expelling into the liquid stream an atomizing gas to atomize the wetting/cleaning liquid expelled from the nozzle. As such, very fine droplets of the wetting/cleaning agent are produced that are capable of entering the small features formed in the wafer, thereby to wet the feature, expel, or absorb gas that may be trapped in the feature, as well as remove debris or contaminants in the feature. The droplets are of a size smaller than the size of the features being wetted and cleaned. A source of atomizing gas is schematically shown in FIG. 1 as 23.

A benefit of using the gas atomizing nozzle is that it will accelerate small liquid particles to high velocities, which enables a mechanical cleaning action as well as delivering the wetting fluid to the target feature. This achieves the dual goals of the prewetting process to fill the feature and remove any residue from preceding processing steps.

Atomizing spray nozzles are articles of commerce. Examples of spray nozzles 20 that may be used in conjunction with the processing system 10 include the VAA to 1J series nozzles, manufactured by Spraying Systems.

FIG. 1 discloses the use of a single spray nozzle 20; however more than one spray nozzle may be employed Moreover, the additional spray nozzle(s) 20 can be mounted on swing arm 30 or on one or more additional swing arms.

The wetting/cleaning agent used in the processing system 10 may consist of deionized water or other aqueous solution.

The atomizing gas may consist of simply air. However, it can be advantageous to utilize an atomizing gas that has a higher solubility with the wetting agent than oxygen. In this manner, an atomizing gas will be absorbed by the wetting agent to a greater extent than the absorption of oxygen by the wetting agent. Such atomizing gases may include, for example, carbon dioxide, nitrogen, helium, clean dry air.

Also, it may be beneficial to modulate or change the atomizing gas used to achieve a different and desired effect to different stages of the wetting and cleaning process. For example, nitrogen can be used to clean the substrate features and CO₂ can be use for wetting the substrate features. As such the atomizing gases can be selected by parameters, such as solubility in water to achieve a desired process effect.

Various ratios of the wetting/cleaning agent and atomizing gas may be used. For example, from 1 to 1500 milliliters per minute of wetting agent may be used and from 15 to 200 liters per minute of atomizing gas may be used. However, more typically it is expected that the wedding agent may be supplied at a volume of 1 to 100 milliliters per minute and the atomizing gas may be supplied at a rate of about 15 to 100 liters per minute. Of course, other ratios of wedding agent and atomizing guests may be employed.

As noted above, the wafer may be rotated while it is being treated with the gas atomized wetting/cleaning agent. The rotational speed of the wafer may be from 1 to 1000 revolutions per minute. Likely, more typically the rotational speed of the wafer will be from about 1 to 500 revolutions per minute. Also, the rotational speed of the wafer may vary during the processing of the wafer. For example, the rotational speed of the wafer may be slower at the beginning and end of the processing duration than during the middle of the process.

The duration of the wetting and cleaning process may vary depending on certain factors, including the number and size of the features in the wafer, the extent that the wafer needs to be cleaned, the extent of gases trapped in the futures, the flow rate of the cleaning agent and atomizing gas expelled by the atomizing nozzle, the size of the wafer, etc. For example, the duration of the wedding and cleaning process may be from 30 to 500 seconds. However, more likely the duration that the gas atomized spray is directed to the wafer will be in the order of about 30 to 120 seconds.

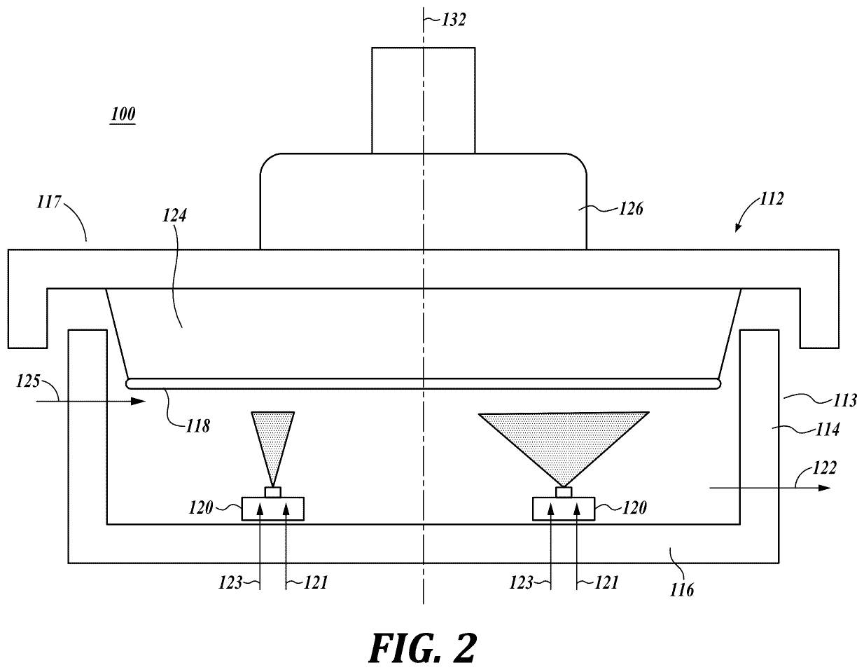

FIG. 2 illustrates another embodiment of the present disclosure wherein the processing system 100 employs a processing chamber 112 composed of a base unit 113 and the top structure 117. As in the base unit 13, the base unit 113 includes sidewalls 114 and the base 116. A drain 122 is provided to remove the wetting fluid from the chamber 112.

The top structure 117 is in the form of a rotatable head that includes an outer rim 119 that extends downwardly to overlap the sidewalls 114 of the base unit 113. Nonetheless the chamber 112 is open to the ambient. The top structure 117 is supported for rotation by a motor 126 that rotates about an axis 132. The motor 124 rotates both the top structure 117 and an underlying chuck 124 that is used to hold a wafer 118 in place for rotation about axis 132.

At least one spray nozzle 120 is mounted in the base unit 113 to direct a gas atomized wetting and cleaning agent upwardly to the underside of the wafer being held by the chuck 124. The spray nozzles 120 may be mounted so as to move about within the base unit 113 so as to direct the gas atomized wetting and cleaning agent at different positions about the wafer 118.

A purge gas may be applied to the interior of the chamber 112 to help direct the air entrapped in the wafer features out of the chamber 112. The purge gas may consist of CO₂, Nitrogen, air.

Use of CO₂ as the purge gas has the advantage of having a higher solubility with the wetting agent than oxygen. In this manner the purge gas will be absorbed by the wetting/cleaning agent to a greater extent than the absorption of oxygen by the wetting/cleaning agent.

The flow rate of the purge gas may be from about 1 to 200 liters per minute for a chamber 112 sized to process wafers of various sizes, for example from 100 to 300 mm.

The flow rates of the wetting/cleaning fluid and atomizing gas may be the same or similar to that noted above with respect to the system 10. Also, the processing time (spray time) used in the processing system 100 may be the same or similar to that noted above relative to the system 10. Further the spin/rotational speed of the wafer 118 may be the same or similar to the spin speed of the wafer 18 noted above.

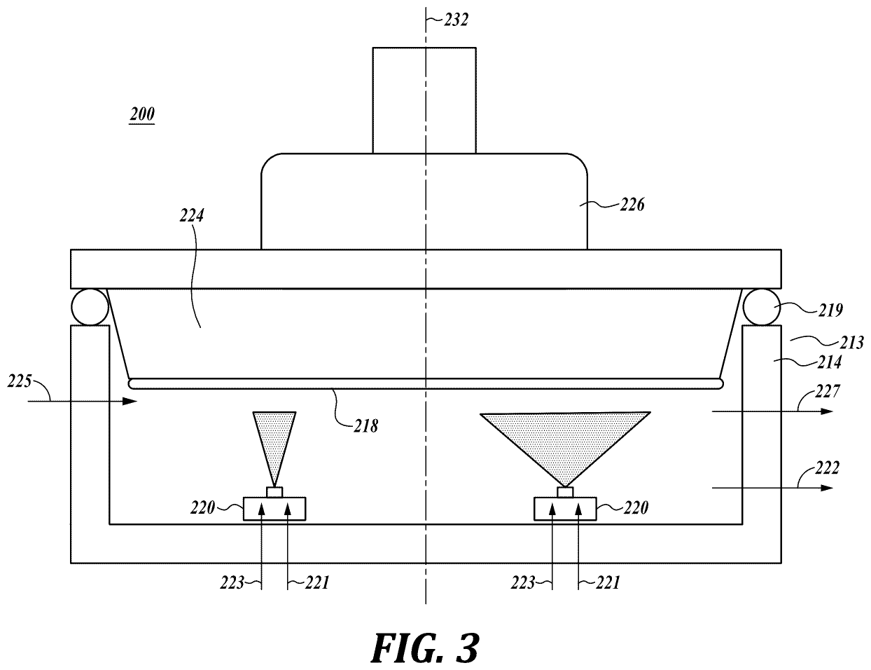

FIG. 3 illustrates another embodiment of the present disclosure wherein the processing system 200 employs a processing chamber 212 composed of a base unit 213 and the top structure 217 in the form of a rotatable head. As in the base unit 113, the base unit 213 includes sidewalls 214 and a base 216. A drain 222 is provided to remove the wetting/cleaning fluid from the chamber 212.

As in processing system 100, the processing system 200 also includes a top structure 217 in the form of a rotatable head that is supported for rotation by a motor 226 that rotates about an axis 232. The motor 224 rotates both the top structure 217 and an underlying chuck 224 that is used to hold a wafer 218 in place for rotation about axis 232.

However, unlike the processing system 100, the processing system 200 is sealed relative to the ambient. In this regard, a seal 219 is disposed between the top structure 217 and base unit 213. The seal permits relative rotation between the top structure and the base unit while permitting a controlled atmosphere to exist within the chamber 212.

The controlled atmosphere enables a desired concentration of ambient or purge gas to be injected into the chamber 112 from a source 225, whether the ambient gas is composed of CO₂, Nitrogen, air, or a mixture thereof. As noted above, the use of CO₂ as the ambient/purge gas has the advantage of a higher solubility with the wetting agent than oxygen. In this manner, the ambient/purge gas will be absorbed by the wetting/cleaning agent to a greater extent than the absorption of oxygen by the wetting/cleaning agent.

As a non-limiting example, the concentration of ambient gas in the chamber 112 may be in excess of 90% by volume.

The ambient/purge gas used in the chamber may be different from the atomizing gas to influence gas concentration in the wetting/cleaning fluid throughout the process. For example, during the atomizing spray the wetting/cleaning fluid may become saturated with the atomizing gas but may be introduced to the sealed environment with a high concentration of a desired process (ambient/purge) gas. The wetting and cleaning fluid would then have the capacity to further dissolve the process gas, despite being saturated with the atomizing gas.

In addition, a vacuum can be created in the chamber 212. The vacuum facilitates the removal and/or dissolving of gases trapped in semiconductor features. In this regard, the pressure within the chamber 212 may be in the range of from 20 to 150 torr. A source of vacuum 227 may be in flow communication with the chamber 212.

In substantially all other respects, the processing system 200 may be the same as or similar to the processing system 100, including the construction and operation of the spray nozzles 220 and the flow rate of the atmospheric gas into the chamber 212.

Further, the flow rates of the wetting/cleaning fluid and atomizing gas may be the same or similar to that noted above with respect to the system 100. Also, the processing time (spray time) used in the processing system 200 may be the same or similar to that noted above relative to the system 100. Further, the spin speed of the wafer 218 may be the same or similar to the spin speed of the wafer 118 noted above.

While illustrative embodiments have been illustrated and described, it will be appreciated that various changes can be made therein without departing from the spirit and scope of the invention.

1. A method of processing a semiconductor substrate defining a plurality of features, the method comprising:
spraying the substrate with a gas atomized wetting and cleaning agent;
rotating the semiconductor substrate during the spraying; and
wetting and cleaning the plurality of features defined in the substrate with the gas atomized wetting and cleaning agent.

2. The method of claim 1, wherein the atomizing gas has a higher solubility in the wetting and cleaning agent than oxygen.

3. (canceled)

4. The method of claim 1, wherein the atomizing gas is selected from the group consisting of carbon dioxide, nitrogen, air.

5. The method of claim 1, further comprising moving the spray of the gas atomized wetting and cleaning agent about the surface of the semiconductor substrate.

6. The method of claim 1, further comprising applying a purge gas to the semiconductor substrate, the purge gas selected from the group consisting of carbon dioxide, common nitrogen, air.

7. The method of claim 1, wherein the semiconductor wafer is located in an atmosphere selected from the group consisting of an open atmosphere environment and a closed atmosphere environment.

8. The method of claim 7, further comprising applying a vacuum to the semiconductor substrate.

9. The method of claim 1, wherein the gas atomized wetting and cleaning fluid comprising:
1-1500 milliliter per minute of wetting and cleaning agent; and
15-200 liters per minute of atomizing gas.

10. (canceled)

11. The method of claim 1, wherein the processing duration is from selected from the group consisting of 30 to 500 seconds and 30 to 120 seconds.

12. The method of claim 1, wherein the rotational speed of the substrate is selected from the group consisting of from 1 to 1000 revolutions per minute and from 1 to 500 revolutions per minute.

13. A method of treating a semiconductor substrate defining a plurality of features with a wetting and cleaning agent, comprising:
forming in an atmosphere within which the semiconductor substrate is disposed a gas having a higher solubility with the wetting agent then oxygen;
spraying the substrate with a gas atomized wetting and cleaning agent; and
wetting and cleaning the plurality of features defined in the substrate with the gas atomized wetting and cleaning agent.

14. The method of claim 13, wherein the atomizing gas is selected from the group consisting of carbon dioxide, nitrogen and air.

15. The method of claim 14, wherein the wetting and cleaning agent is selected from the group consisting of deionized water, aqueous solution.

16-20. (canceled)

21. A semiconductor substrate wetting and cleaning system, comprising:
a processing chamber;
a rotatable head disposed in the processing chamber;
a coupler for coupling a semiconductor substrate to the rotatable head;
at least one gas atomized spray nozzle directed at the semiconductor substrate when coupled to the coupler;
a source of pre-wetting and cleaning fluid in flow communication with the spray nozzle; and
a source of atomizing gas in flow communication with the spray nozzle.

22. The system of claim 21, wherein the pre-wetting fluid is selected from the group consisting of deionized water and aqueous solution.

23. The system of claim 21, wherein the atomizing gas is selected from the group consisting of carbon dioxide, nitrogen, air.

24. The system of claim 21, comprising a plurality of gas atomized spray nozzles configured to move about the semiconductor substrate.

25. The system of claim 21, further comprising an actuator to which the at least one atomizing spray nozzle is mounted, the actuator moving the at least one atomizing spray nozzle about the area of the semiconductor substrate.

26. (canceled)

27. The system of claim 21, wherein the chamber is closed relative to the ambient.

28. The system of claim 27, further comprising a source of vacuum in flow communication with the processing chamber.
